(19) United States
(12) Patent Application Publication
(10) Pub. No.: US 2016/0195583 A1
(43) Pub. Date: Jul. 7, 2016

(54) FAULT DIAGNOSING METHOD BASED ON STANDARD DEVIATION OF DETAIL COEFFICIENTS FOR POWER CONVERTER OF SWITCHED RELUCTANCE MOTOR

(71) Applicant: CHINA UNIVERSITY OF MINING AND TECHNOLOGY, Xuzhou, Jiangsu (CN)

(72) Inventors: Hao CHEN, Xuzhou (CN); Guoqiang HAN, Xuzhou (CN); Xing WANG, Xuzhou (CN)

(21) Appl. No.: 14/911,425

(22) PCT Filed: Mar. 26, 2014
(86) PCT No.: PCT/CN2014/074097

§ 371 Date: Feb. 10, 2016

(30) Foreign Application Priority Data
Sep. 23, 2013 (CN) 201310436418.2

(51) Int. Cl. G01R 31/34; G01R 31/42

(52) U.S. Cl. CPC G01R 31/343; G01R 31/42

(57) ABSTRACT

A fault diagnosing method based on standard deviation of detail coefficients for the power converter of a switched reluctance motor, operates by detecting the transient value of phase current in the power converter of a switched reluctance motor, the standard deviation of detail coefficients a is calculated and is taken as a fault characteristic quantity, and then whether there is a short circuit fault in the main switch of the power converter of the switched reluctance motor is diagnosed with a curve of standard deviation of detail coefficients a of phase current in the power converter of the switched reluctance motor in the entire range of rotation speed or in the entire range of torque. The method is applicable to the power converter of a switched reluctance motor with any topological structure, with any number of phases, can diagnose short circuit faults accurately, and has a great value in engineering application.

### FIELD OF THE INVENTION

The present invention relates to a short circuit fault diagnosing method based on standard deviation of detail coefficients, in particular to a short circuit fault diagnosing method based on standard deviation of detail coefficients for the power converter of a switched reluctance motor with any number of phases.

### BACKGROUND OF THE INVENTION

Though the research on fault detection and diagnostic techniques for switched reluctance motor system has received extensive attention gradually in all countries around the world, only a few of achievement have been obtained since its late start. The research on fault diagnosis of switched reluctance motor system is mainly based on qualitative theoretical analysis or comparative analysis of system performance in normal state and fault state. The power converter is an important component of a switched reluctance motor system and is a fault prone point. Most fault protection measures for power converters are still at the level of protection for power devices against over-current, over-voltage, and overheat, and are not effective until the fault has developed to a level that it affects characteristics of externally measurable variables, in addition, owing to the difference in system structure and parameters, only a threshold for fault protection can be set roughly, but the fault type cannot be judged. The strong nonlinear characteristic and unique control mode of switched reluctance motor system itself also bring considerable difficulties to the research of system fault diagnosis, and conventional fault diagnosing methods for power converters cannot be directly applied to the power converters of switched reluctance motors.

### SUMMARY OF THE INVENTION

To solve the technical problems in the prior art, the present invention provides a short circuit fault diagnosing method based on standard deviation of detail coefficients for the power converter of a switched reluctance motor.

The fault diagnosing method based on standard deviation of detail coefficients for the power converter of a switched reluctance motor in the present invention comprises:

detecting the transient value of phase current f(t) in the power converter of a switched reluctance motor; and, with the following expression:

$$σ = \sqrt{\frac{1}{k} {( {d}_{j , k} - \overline{{d}_{j , k}} )}^{2}}$$

the standard deviation of detail coefficients σ is calculated, wherein, the real values of detail coefficients are d_{j,k}=∫_{R}f(t)2^{-j/2}φ̅(̅2̅^̅{̅-̅j̅}̅t̅−̅k̅)̅dt, the mean values of detail coefficients are

$$\overline{{d}_{j , k}} = \frac{1}{k} {\sum }_{k} {d}_{j , k} ,$$

t is time variable, j is resolution level, k is discretized translation value, φ(2^{-j}t−k) is the conjugate complex of wavelet function φ(2^{-j}t−k), and R is the integral range of time, carrying out a transformation for the transient value of phase current f(t) as follows:

$$f ( t ) = {\sum }_{j = 1} {\sum }_{k} {c}_{j , k} {2}^{- j / 2} ϕ ( {2}^{- j} t - k ) + {\sum }_{j = 1} {\sum }_{k} {d}_{j , k} {2}^{- j / 2} φ ( {2}^{- j} t - k ) ,$$

wherein, the scale factor is c_{j,k}=∫_{R}f(t)2^{-j/2}φ̅(̅2̅^̅{̅-̅j̅}̅t̅−̅k̅)̅d̅t̅, and φ̅(̅2̅^̅{̅-̅j̅}̅t̅−̅k̅)̅ is the conjugate complex of scale function φ(2^{-j}t−k);
taking the standard deviation of detail coefficients σ as a fault characteristic quantity to diagnose whether there is any short circuit fault in the main circuit of the power converter of the switched reluctance motor;
if the standard deviation of detail coefficients a in the entire range of rotation speed fluctuates between 0.005 and 0.01 or if the standard deviation of detail coefficients a in the entire range of torque fluctuates near 0.005, it indicates that a short circuit fault has occurred in the power converter of the switched reluctance motor.

Beneficial effects: the present invention is applicable to the diagnosis of short circuit faults in the power converter of a switched reluctance motor with any topological structures, with any number of phases. By detecting the transient value of phase current in the power converter of a switched reluctance motor, the standard deviation of detail coefficients σ is calculated and taken as a fault characteristic quantity, by a curve of standard deviation of detail coefficients σ of phase current in the power converter of the switched reluctance motor in the entire range of rotation speed or a curve of standard deviation of detail coefficients σ of phase current in the power converter of the switched reluctance motor in the entire range of torque, a short circuit fault in the power converter of the switched reluctance motor is diagnosed, so as to attain the object of the present invention. The fault diagnosing method for the power converter of a switched reluctance motor can extract a fault characteristic quantitatively, is ideal for diagnosis of short circuit fault, can achieve reliable and accurate fault diagnosis, and has a great value in engineering application.

### BRIEF DESCRIPTION OF THE DRAWINGS

FIG. 1 is a topological structure diagram of a three-phase dual-switch power converter of a switched reluctance motor, for which the present invention is applied;

FIG. 2 is a curve diagram of standard deviation of detail coefficients a of a three-phase dual-switch power converter of a switched reluctance motor in the entire range of rotation speed, for which the present invention is applied;

FIG. 3 is a curve diagram of standard deviation of detail coefficients a of a three-phase dual-switch power converter of a switched reluctance motor in the entire range of torque, for which the present invention is applied.

### DETAILED DESCRIPTION OF THE EMBODIMENTS

Hereunder the present invention will be further detailed in an embodiment, with reference to the accompanying drawings:

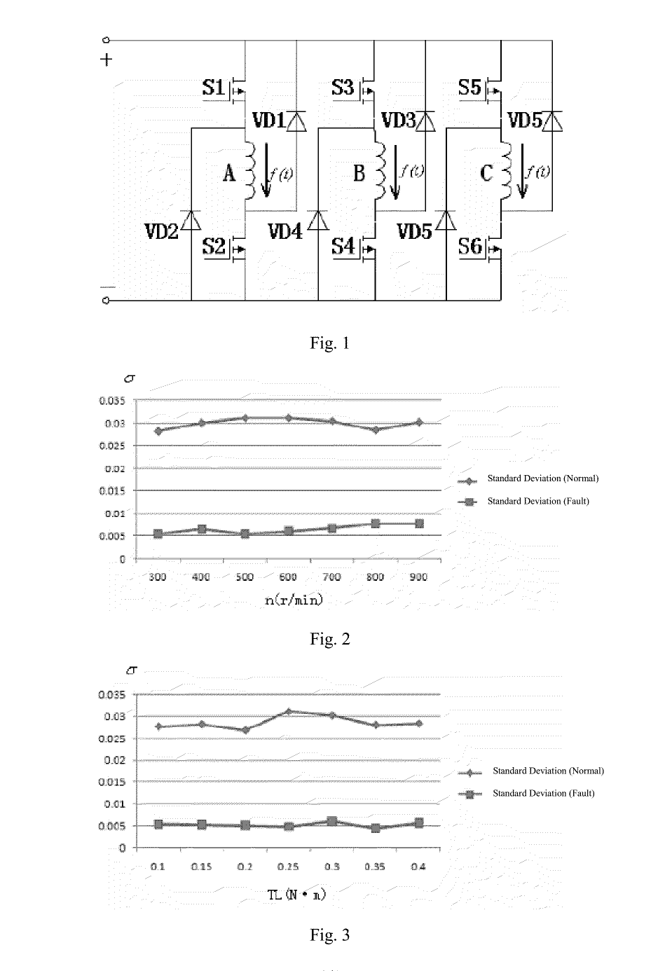

As shown in FIG. 1, in the main circuit of a three-phase dual-switch power converter of a switched reluctance motor, each phase in the three-phase dual-switch power converter has two main switches and two flywheel diodes, and phases A, B, and C are connected in parallel to the positive pole “+” and negative pole “−” of power supply. Wherein, one end of the upper main switch S1 of phase A is connected to the positive pole “+” of the power supply, the other end of the upper main switch S1 is connected to one end of the winding of phase A, one end of the lower main switch S2 is connected to the negative pole “−” of the power supply, the other end of the lower main switch S2 is connected to the other end of the winding of phase A, one end of the upper flywheel diode VD1 is connected to the positive pole “+” of the power supply, the other end of the upper flywheel diode VD1 is connected to the other end of the winding of phase A, one end of the lower flywheel diode VD2 is connected to the negative pole “−” of the power supply, and the other end of the lower flywheel diode VD2 is connected to one end of the winding of phase A. The internal connections in phase B and phase C are identical to the internal connections in phase A, therefore, the description is omitted here. The fault diagnosing method based on standard deviation of detail coefficients for the power converter of a switched reluctance motor is as follows:

First, the transient value of phase current f(t) of phase A in the three-phase dual-switch power converter of a switched reluctance motor is detected; and, with the following expressions:

$$σ = \sqrt{\frac{1}{k} {( {d}_{j , k} - \overline{{d}_{j , k}} )}^{2}}$$

the standard deviation of detail coefficients σ is calculated, wherein, the real values of detail coefficients are d_{j,k}=∫_{R}f(t)2^{-j/2}φ̅(̅2̅^̅{̅-̅j̅}̅t̅−̅k̅)̅dt, the mean values of detail coefficients are

$$\overline{{d}_{j , k}} = \frac{1}{k} {\sum }_{k} {d}_{j , k} ,$$

t is time variable, j is resolution level, k is discretized translation value, φ̅(̅2̅^̅{̅-̅j̅}̅t̅−̅k̅)̅ is the conjugate complex of wavelet function φ(2^{-j}t−k), and R is the integral range of time, a transformation is carried out for the transient value of phase current f(t) as follows:

$$f ( t ) = {\sum }_{j = 1} {\sum }_{k} {c}_{j , k} {2}^{- j / 2} ϕ ( {2}^{- j} t - k ) + {\sum }_{j = 1} {\sum }_{k} {d}_{j , k} {2}^{- j / 2} φ ( {2}^{- j} t - k ) ,$$

wherein, the scale factor is c_{j,k}=∫_{R}f(t)2^{-j/2}φ̅(̅2̅^̅{̅-̅j̅}̅t̅−̅k̅)̅dt, and φ̅(̅2̅^̅{̅-̅j̅}̅t̅−̅k̅ ) is the conjugate complex of scale function φ(2^{-j}t−k);
the standard deviation of detail coefficients σ is taken as a fault characteristic quantity, to diagnose whether there is any short circuit fault in the main circuit of the power converter of the switched reluctance motor;
as shown in FIG. 2, if the standard deviation of detail coefficients σ in the entire range of rotation speed fluctuates between 0.005 and 0.01, or, as shown in FIG. 3, if the standard deviation of detail coefficients σ in the entire range of torque fluctuates near 0.005, it indicates that a short circuit fault has occurred in phase A of the dual-switch power converter of the switched reluctance motor.

The fault detection, fault type identification, and fault phase locating method is similar to that for phase A of the dual-switch power converter of the switched reluctance motor, when there is short circuit fault in phase B of the three-phase dual-switch power converter of the switched reluctance motor; The transient value of phase current f(t) of phase B in the three-phase dual-switch power converter of the switched reluctance motor is detected; and, with the following expressions:

$$σ = \sqrt{\frac{1}{k} {( {d}_{j , k} - \overline{{d}_{j , k}} )}^{2}}$$

the standard deviation of detail coefficients σ is calculated, wherein, the real values of detail coefficients are d_{j,k}=∫_{R}f(t)2^{-j/2}φ̅(̅2̅^̅{̅-̅j̅}̅t̅−̅k̅)̅dt, the mean values of detail coefficients are

$$\overline{{d}_{j , k}} = \frac{1}{k} {\sum }_{k} {d}_{j , k} ,$$

t is time variable, j is resolution level, k is discretized translation value, φ̅(̅2̅^̅{̅-̅j̅}̅t̅−̅k̅)̅ is the conjugate complex of wavelet function φ(2^{-j}t−k), and R is the integral range of time, a transformation is carried out for the transient value of phase current f(t) as follows:

$$f ( t ) = {\sum }_{j = 1} {\sum }_{k} {c}_{j , k} {2}^{- j / 2} ϕ ( {2}^{- j} t - k ) + {\sum }_{j = 1} {\sum }_{k} {d}_{j , k} {2}^{- j / 2} φ ( {2}^{- j} t - k ) ,$$

wherein, the scale factor is c_{j,k}=∫_{R}f(t)2^{-j/2}φ̅(̅2̅^̅{̅-̅j̅}̅t̅−̅k̅)̅dt, and φ̅(̅2̅^̅{̅-̅j̅}̅t̅−̅k̅)̅ is the conjugate complex of scale function φ(2^{-j}t−k);
the standard deviation of detail coefficients a is taken as a fault characteristic quantity to diagnose whether there is any short circuit fault in the main circuit of the power converter of the switched reluctance motor;
as shown in FIG. 2, if the standard deviation of detail coefficients a in the entire range of rotation speed fluctuates between 0.005 and 0.01, or, as shown in FIG. 3, if the standard deviation of detail coefficients a in the entire range of torque fluctuates near 0.005, it indicates that a short circuit fault has occurred in phase B of the dual-switch power converter of the switched reluctance motor.

The fault detection, fault type identification, and fault phase locating method is similar to that for phase A of the dual-switch power converter of the switched reluctance motor, when there is short circuit fault in phase C of the three-phase dual-switch power converter of the switched reluctance motor;

The transient value of phase current f(t) of phase C in the three-phase dual-switch power converter of the switched reluctance motor is detected; and, with the following expressions:

$$σ = \sqrt{\frac{1}{k} {( {d}_{j , k} - \overline{{d}_{j , k}} )}^{2}}$$

the standard deviation of detail coefficients a is calculated, wherein, the real values of detail coefficients are d_{j,k}=∫_{R}f(t)2^{-j/2}φ̅(̅2̅^̅{̅-̅j̅}̅t̅−̅k̅)̅dt, the the mean values of detail coefficients are

$$\overline{{d}_{j , k}} = \frac{1}{k} {\sum }_{k} {d}_{j , k} ,$$

t is time variable, j is resolution level, k is discretized translation value, φ̅(̅2̅^̅{̅-̅j̅}̅t̅−̅k̅)̅ is the conjugate complex of wavelet function φ(2^{-j}t−k), is the integral range of time, a transformation is carried out for the transient value of phase current f(t) as follows:

$$f ( t ) = {\sum }_{j = 1} {\sum }_{k} {c}_{j , k} {2}^{- j / 2} ϕ ( {2}^{- j} t - k ) + {\sum }_{j = 1} {\sum }_{k} {d}_{j , k} {2}^{- j / 2} φ ( {2}^{- j} t - k ) ,$$

wherein, the scale factor is c_{j,k}=∫_{R}f(t)2^{-j/2}φ̅(̅2̅^̅{̅-̅j̅}̅t̅−̅k̅)̅dt, and φ̅(̅2̅^̅{̅-̅j̅}̅t̅−̅k̅)̅ is the conjugate complex of scale function φ(2^{-j}t−k);
the standard deviation of detail coefficients σ is taken as a fault characteristic quantity to diagnose whether there is any short circuit fault in the main circuit of the power converter of the switched reluctance motor;
as shown in FIG. 2, if the standard deviation of detail coefficients σ in the entire range of rotation speed fluctuates between 0.005 and 0.01, or, as shown in FIG. 3, if the standard deviation of detail coefficients σ in the entire range of torque fluctuates near 0.005, it indicates that a short circuit fault has occurred in phase C of the dual-switch power converter of the switched reluctance motor.

The fault detection, fault type identification, and fault locating method is similar to the method described above, when there is lower tubes short circuit fault simultaneously in two or more phases of the power converter of the switched reluctance motor.

By detecting the phase current of phase A, B, and C respectively, whether the standard deviation of detail coefficients σ in the entire range of rotation speed fluctuates between 0.005 and 0.01, or whether the standard deviation of detail coefficients σ in the entire range of torque fluctuates near 0.005 is diagnosed, so as to locate the phase in fault.

1. A fault diagnosing method based on standard deviation of detail coefficients for the power converter of a switched reluctance motor, comprising:
detecting the transient value of phase current f(t) in the power converter of a switched reluctance motor; and, with the following expression:
$$σ = \sqrt{\frac{1}{k} {( {d}_{j , k} - \overline{{d}_{j , k}} )}^{2}}$$
calculating the standard deviation of detail coefficients σ, wherein, the real values of detail coefficients are d_{j,k}=∫_{R}f(t)2^{-j/2}φ̅(̅2̅^̅{̅-̅j̅}̅t̅−̅k̅)̅dt, the mean values of detail coefficients are
$$\overline{{d}_{j , k}} = \frac{1}{k} {\sum }_{k} {d}_{j , k} ,$$
t is time variable, j is resolution level, k is discretized translation value, φ̅(̅2̅^̅{̅-̅j̅}̅t̅−̅k̅)̅ is the conjugate complex of wavelet function φ(2^{-j}t−k), and R is the integral range of time, carrying out a transformation for the transient value of phase current f(t) as follows:
$$f ( t ) = {\sum }_{j = 1} {\sum }_{k} {c}_{j , k} {2}^{- j / 2} ϕ ( {2}^{- j} t - k ) + {\sum }_{j = 1} {\sum }_{k} {d}_{j , k} {2}^{- j / 2} φ ( {2}^{- j} t - k ) ,$$
wherein, the scale factor is c_{j,k}=∫_{R}f(t)2^{-j/2}φ̅(̅2̅^̅{̅-̅j̅}̅t̅−̅k̅)̅dt, and φ̅(̅2̅^̅{̅-̅j̅}̅t̅−̅k̅)̅ is the conjugate complex of scale function φ(2^{-j}t−k); taking the standard deviation of detail coefficients a as a fault characteristic quantity to diagnose whether there is any short circuit fault in the main circuit of the power converter of the switched reluctance motor;
wherein if the curve of standard deviation of detail coefficients σ in the entire range of rotation speed fluctuates between 0.005 and 0.01 or if the curve of standard deviation of detail coefficients σ in the entire range of torque fluctuates near 0.005, it indicates that a short circuit fault has occurred in the power converter of the switched reluctance motor.
